(19) United States
(12) Patent Application Publication
(10) Pub. No.: US 2025/0126712 A1
(43) Pub. Date: Apr. 17, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Young Kuk Ko, Suwon-si (KR); Sanghoon Kim, Suwon-si (KR); Jiho Yoon, Suwon-si (KR); Gyumook Kim, Suwon-si (KR); Taehun Kim, Suwon-si (KR); Heasung Kim, Suwon-si (KR)

(73) Assignee: SAMSUNG ELECTRO-MECHANICS CO., LTD., Suwon-si (KR)

(21) Appl. No.: 18/768,907

(22) Filed: Jul. 10, 2024

(30) Foreign Application Priority Data
Oct. 13, 2023 (KR) 10-2023-0137104

(51) Int. Cl. H05K 1/11; H05K 1/02; H05K 3/46

(52) U.S. Cl. CPC H05K 1/115; H05K 1/0298; H05K 3/4644; H05K 2201/096; H05K 2201/2081

(57) ABSTRACT

A printed circuit board according to an embodiment includes: a first insulating layer; a first wiring layer buried in the first insulating layer; a first via disposed within a first via hole in the first insulating layer; a second insulating layer disposed below the first insulating layer; a second wiring layer buried in the second insulating layer; a first solder resist layer disposed on the first insulating layer; and a cavity extending along a height direction by penetrating the first solder resist layer and penetrating a portion of the first insulating layer. The cavity includes a first portion, a second portion, and a third portion having different 10 widths. Along the height direction, the first portion is disposed on the second portion and the third portion is disposed on the first portion. The first via is exposed through the second portion of the cavity.

### CROSS-REFERENCE TO RELATED APPLICATION

This application claims priority to and the benefit of Korean Patent Application No. 10-2023-0137104 filed at the Korean Intellectual Property Office on Oct. 13, 2023, the entire contents of which are incorporated herein by reference.

### TECHNICAL FIELD

The present disclosure relates to a printed circuit board and a manufacturing method thereof.

### BACKGROUND

A printed circuit board forms a circuit pattern at an insulating material using a conductive material such as copper. As electronic devices in an IT field including a mobile phone become smaller, a method of forming a cavity at the printed circuit board and mounting an electronic component such as an IC, an active element, a passive element, or the like within the cavity has been proposed.

A height of a portion of the electronic component mounted within the printed circuit board may change depending on a depth of the cavity of the printed circuit board where the electronic component is mounted.

As a depth of the cavity of the printed circuit board increases, a large portion of the electronic component may be mounted within the cavity, and an entire thickness of a product packaging the electronic component and the printed circuit board may be reduced.

However, when the cavity is formed at the printed circuit board, it is difficult to adjust the depth of the cavity, and a peripheral circuit pattern may be damaged to deepen the depth of the cavity.

Additionally, if a size of a mounting connection portion between the electronic component mounted within the cavity and the board is small, it may be difficult to accurately mount the electronic component at the board.

### SUMMARY

Embodiments are to provide a printed circuit board and a manufacturing method thereof capable of forming a cavity that may have a desired depth and may increase mounting accuracy without damaging a circuit pattern around the cavity.

However, problems to be solved by the embodiments are not limited to the above-described problem and may be variously extended in a range of technical ideas included in the embodiments.

A printed circuit board according to an embodiment includes: a first insulating layer; a first wiring layer that is buried in the first insulating layer; a first via that is disposed within a first via hole in the first insulating layer; a second insulating layer that is disposed below the first insulating layer; a second wiring layer that is buried in the second insulating layer; a first solder resist layer that is disposed on the first insulating layer; and a cavity that extends along a height direction by penetrating the first solder resist layer and penetrating a portion of the first insulating layer. The cavity includes a first portion, a second portion, and a third portion having different widths. Along the height direction, the first portion is disposed on the second portion and the third portion is disposed on the first portion. The first via is exposed through the second portion of the cavity.

The second portion of the cavity may be plural in number, and a surface of the first insulating layer between the plurality of second portions included in the cavity may have a plurality of protrusions protruding toward the first portion.

Each of the first via hole and the first via may be plural in number, and the plurality of the second portions may overlap the plurality of the first vias along the height direction.

A first width of the first portion, a second width of the second portion, and a third width of the third portion may be different from each other.

The second width of the second portion may be less than each of the first width of the first portion and the third width of the third portion.

A first depth of the first portion may be substantially equal to a first thickness of the first wiring layer, and a second depth of the second portion may be less than a second thickness of the first via.

A third depth of the third portion may be substantially equal to a third thickness of the first solder resist layer.

The printed circuit board may further include: a second via disposed within a second via hole in the second insulating layer; a third insulating layer disposed below the second insulating layer; and a third via disposed within a third via hole in the third insulating layer.

The printed circuit board may further include: a first pad layer buried by the first solder resist layer; a first additional pad layer disposed within a cutout portion of the first solder resist layer and contacting the first pad layer; and a second additional pad layer disposed on the first additional pad layer.

The cavity may further include a fourth portion defined by a side surface of the second additional pad layer.

A width of the fourth portion may be different from a first width of the first portion, a second width of the second portion, and a third width of the third portion.

A manufacturing method of the printed circuit board according to an embodiment includes: forming a first wiring layer and a first sacrificial layer; forming a plurality of dummy patterns on the first sacrificial layer; forming a first insulating layer burying the first wiring layer, the first sacrificial layer, and the plurality of dummy patterns; forming a first via hole overlapping the first wiring layer and a plurality of second via holes overlapping the plurality of dummy patterns in the first insulating layer; forming a first via and a plurality of second vias in the first via hole and the plurality of second via holes of the first insulating layer; forming a second sacrificial layer on the first sacrificial layer; forming a first portion of a cavity by etching the second sacrificial layer and the first sacrificial layer; and removing the plurality of dummy patterns to form a second portion of the cavity so that the plurality of second vias are exposed.

The first sacrificial layer may be disposed on a side surface of the first wiring layer and may be formed to have the same thickness as that of the first wiring layer, and the plurality of dummy patterns may be disposed on a side surface of the first via and may be formed to have a thickness less than a thickness of the first via.

The manufacturing method may further include: forming a pad layer that is the same layer as the second sacrificial layer on the first wiring layer; and forming a first solder resist layer that covers the pad layer, exposes the second sacrificial layer, and has a third portion of the cavity.

The manufacturing method may further include: forming a second insulating layer disposed below the first insulating layer; and forming a third via disposed within a third via hole formed in the second insulating layer.

The manufacturing method may further include: forming a first additional pad layer disposed within a cutout portion of the first solder resist layer and contacting the pad layer; and forming a second additional pad layer disposed on the first additional pad layer.

The cavity may be formed to further include a fourth portion defined by a side surface of the second additional pad layer.

A first width of the first portion, a second width of the second portion, and a third width of the third portion may be differently formed.

The second width of the second portion may be formed to be less than each of the first width of the first portion and the third width of the third portion.

A width of the fourth portion may be formed differently from the first width of the first portion, the second width of the second portion, and the third width of the third portion.

According to the embodiments, a printed circuit board and a manufacturing method thereof capable of forming a cavity that may have a desired depth and may increase mounting accuracy without damaging a circuit pattern around the cavity may be provided.

It is obvious that an effect of the embodiments is not limited to the above-described effect, and may be variously extended without departing from the spirit and scope of the present disclosure.

### BRIEF DESCRIPTION OF THE DRAWINGS

FIG. 1 is a cross-sectional view of a printed circuit board according to an embodiment.

FIGS. 2 to 10 are cross-sectional views showing a manufacturing method of the printed circuit board according to an embodiment.

FIG. 11 is a cross-sectional view of a printed circuit board according to another embodiment.

FIG. 12 is a cross-sectional view of a printed circuit board according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, the accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

Hereinafter, various embodiments and variations will be described in detail with reference to the drawings.

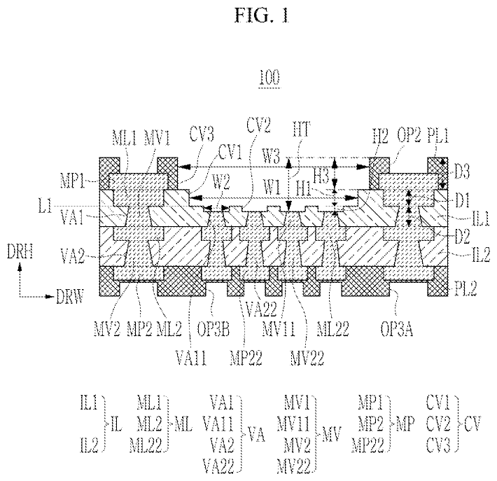

Referring to FIG. 1, a printed circuit board according to an embodiment is described. FIG. 1 is a cross-sectional view of the printed circuit board according to the embodiment.

Referring to FIG. 1, the printed circuit board 100 according to the present embodiment may include a plurality of insulating layers IL that are stacked, a plurality of wiring layers ML buried within the plurality of insulating layers IL, a plurality of vias MV disposed within a plurality of via holes VA of the plurality of insulating layers IL, a plurality of pad layers MP, a solder resist layer PL, and a cavity CV formed in a portion of the plurality of insulating layers IL.

The plurality of insulating layers IL may include a first insulating layer IL1 and a second insulating layer IL2 disposed on the first insulating layer IL1 along a height direction DRH.

The plurality of wiring layers ML may include a first wiring layer ML1 buried by the first insulating layer IL1, and a second wiring layer ML2 and a third wiring layer ML22 buried by the second insulating layer IL2.

The plurality of vias MV may include a first via MV1 disposed within a first via hole VA1 formed in the first insulating layer IL1, a second via MV11 disposed within a second via hole VA11 formed in the first insulating layer IL1, a third via MV2 disposed within a third via hole VA2 formed in the second insulating layer IL2, and a fourth via MV22 disposed within a fourth via hole VA22 formed in the second insulating layer IL2.

The plurality of pad layers MP may include a first pad layer MP1 disposed on the first insulating layer IL1, and a second pad layer MP2 and a third pad layer MP22 disposed below the second insulating layer IL2.

A portion of the first wiring layer ML1 and a portion of the second wiring layer ML2 may be connected through the first via MV1, the second via MV11 may be connected to a portion of the third wiring layer ML22, the portion of the second wiring layer ML2 and the second pad layer MP2 may be connected through the third via MV2, the first pad layer MP1 may be connected to the first wiring layer ML1, and the portion of the third wiring layer ML22 and the third pad layer MP22 may be connected to each other through the fourth via MV22.

The solder resist layer PL may include a first solder resist layer PL1 disposed on the first insulating layer IL1 and exposing a portion of the first pad layer MP1 through an opening OP2, and a second solder resist layer PL2 disposed below the second insulating layer IL2 and exposing portions of the second pad layer MP2 and the third pad layer MP22 through openings OP3A and OP3B.

The cavity CV may include a first portion CV1 and a second portion CV2 formed in the first insulating layer IL1 and having different widths and different heights, and a third portion CV3 formed in the first solder resist layer PL1.

The first portion CV1 of the cavity CV is disposed on a side surface of the first wiring layer ML1, the second portion CV2 of the cavity CV is disposed on a side surface of the first via MV1 and overlaps the second via MV11, and the third portion CV3 of the cavity CV is disposed on a side surface of the first solder resist layer PL1.

Along the height direction DRH, the first portion CV1 of the cavity CV may be disposed on the second portion CV2 of the cavity CV, and the third portion CV3 of the cavity CV may be disposed on the first portion CV1 of the cavity CV.

The second via MV11 may be exposed through the second portion CV2 of the cavity CV within the cavity CV. Along the height direction DRH, a lower surface of the second portion CV2 of the cavity CV and an upper surface of the second via MV11 may have substantially the same height.

Along a plane direction DRW perpendicular to the height direction DRH, the first portion CV1 of the cavity CV formed at the first insulating layer IL1 may have a first width W1, the second portion CV2 of the cavity CV formed at the first insulating layer IL1 may have a second width W2, and the third portion CV3 of the cavity CV formed at a portion of the first solder resist layer PL1 may have a third width W3.

The first width W1 of the first portion CV1 of the cavity CV may be different from the second width W2 of the second portion CV2 of the cavity CV.

The second portion CV2 of the cavity CV may be plural, and may overlap a plurality of second vias MV11. For example, the second width W2 of a corresponding second portion CV2 of the cavity CV may be greater than a width of a corresponding second via MV11 exposed by the corresponding second portion CV2.

Along the height direction DRH, the second portion CV2 of the cavity CV may overlap the first portion CV1 of the cavity CV.

The third width W3 of the third portion CV3 of the cavity CV may be larger than the first width W1 of the first portion CV1 of the cavity CV.

Sidewalls of the cavity CV may not be disposed in a line along the height direction DRH, and may have a step difference.

Along the height direction DRH, a first depth H1 of the first portion CV1 of the cavity CV may be substantially equal to a first thickness D1 of the first wiring layer ML1 buried by the first insulating layer IL1, a second depth H2 of the second portion CV2 of the cavity CV may be less than a second thickness D2 of the first via MV1 disposed within the first via hole VA1 formed in the first insulating layer IL1, and a third depth H3 of the third portion CV3 of the cavity CV may be substantially the same as a third thickness D3 of the first solder resist layer PL1.

Referring to a virtual first line L1 shown in a direction parallel to the plane direction DRW in FIG. 1, the first insulating layer IL1 between a plurality of second portions CV2 of the cavity CV may upwardly protrude, and a height of an upper surface of the protrusion may be substantially the same as a height of a lower surface of the first wiring layer ML1.

According to the printed circuit board according to the present embodiment, the cavity CV may be formed in a portion of the first insulating layer IL1 and the first solder resist layer PL1, and a total depth HT of the cavity CV may be substantially equal to a sum of the first thickness D1 of the first wiring layer ML1 buried by the first insulating layer IL1, a thickness of a portion of the first via MV1 within the first via hole VA1 formed in the first insulating layer IL1, and a thickness of the first solder resist layer PL1. A surface of the first insulating layer IL1 between the second portions CV2 within the cavity CV protrudes so that the plurality of wiring layers ML buried within the plurality of insulating layers IL are not exposed by the cavity CV. Therefore, a circuit pattern around the cavity CV may not be damaged.

In addition, a surface of the first insulating layer IL1 disposed on a side surface of the second portion CV2 of the cavity CV may protrude more than the second portion CV2 so that a plurality of protrusions (PR) are disposed on a surface of a lower surface of the cavity CV and the protrusion (PR) serves as a spacer. The plurality of protrusions (PR) may be further included within the cavity CV so that if an electronic component is mounted within the cavity CV, a space is generated around the electronic component and heat generated by the electronic component or the like is diffused through the space.

In addition, the plurality of second portions CV2 of the cavity CV may overlap the plurality of second vias MV11, and a connection portion for connection between the electronic component to be mounted within the cavity CV and the printed circuit board 100 may be disposed within the plurality of second portions CV2. Thus, even if a size of the connection portion becomes small, the connection portion may be disposed within the plurality of second portions CV2 so that connection between the electronic component and the printed circuit board 100 is safely maintained.

If the electronic component is mounted on a mounting board (not shown), the electronic component may be disposed within the cavity CV of the printed circuit board. Thus, an overall thickness of a package of the electronic component may decrease as a depth of the cavity CV increases.

According to the printed circuit board according to the present embodiment, the cavity CV having a desired depth may be formed without damaging the circuit pattern around the cavity CV so that it is possible to reduce the overall thickness of the package of the electronic component without occurrence of a defect.

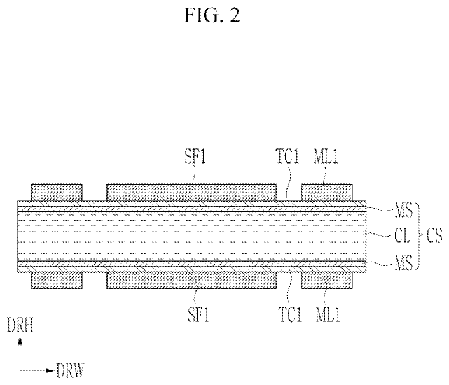

Then, with reference to FIGS. 2 to 10 together with FIG. 1, a manufacturing method of the printed circuit board according to an embodiment will be described. FIGS. 2 to 10 are cross-sectional views showing the manufacturing method of the printed circuit board according to an embodiment.

Referring to FIG. 2, a first copper foil layer TC1 and the first wiring layer ML1 may be formed above or on a carrier substrate (or a carrier board) CS including a core portion CL and thin film metal layers MS stacked at both sides of the core portion CL. In this case, a first sacrificial layer SF1 disposed at a position where the cavity CV will be formed may be together formed. Because the first sacrificial layer SF1 is formed together with the first wiring layer ML1, the first sacrificial layer SF1 may be made of the same material as that of the first wiring layer ML1 and may have the same thickness as the first thickness D1 of the first wiring layer ML1.

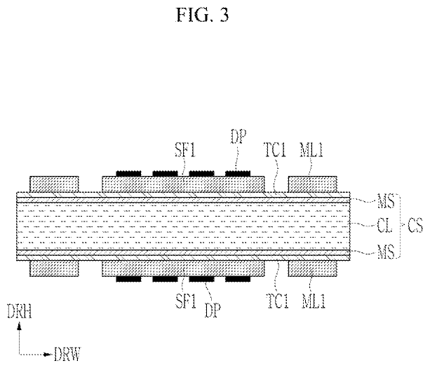

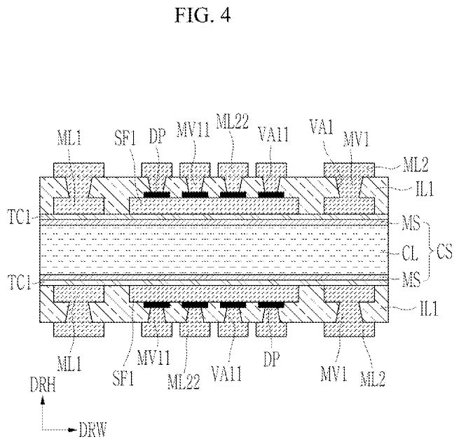

As shown in FIG. 3, a plurality of dummy patterns DP are formed on the first sacrificial layer SF1. The dummy pattern DP may include a layer made of a material different from the wiring layer ML and the via MV. For example, a dummy pattern DP may include nickel, but the embodiment is not limited thereto. As shown in FIG. 4, the first insulating layer IL1 is formed on the first wiring layer ML1, the first sacrificial layer SF1, and the plurality of dummy patterns DP, the first via hole VA1 overlapping the first wiring layer ML1 and the second via hole VA11 overlapping the plurality of dummy patterns DP are formed in the first insulating layer IL1, the first via MV1 disposed within the first via hole VA1 and the second via MV11 disposed within the second via hole VA11 are formed, and the second wiring layer ML2 overlapping the first via MV1 and the third wiring layer ML22 overlapping the second via MV11 are formed.

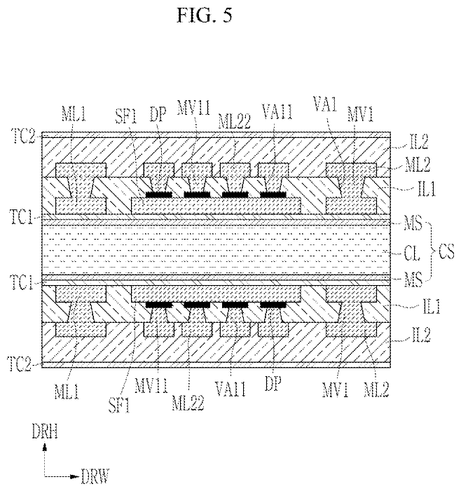

Referring to FIG. 5, the second insulating layer IL2 and a second copper foil layer TC2 are formed above or on the second wiring layer ML2 and the third wiring layer ML22, so that the second wiring layer ML2 and the third wiring layer ML22 are buried by the second insulating layer IL2.

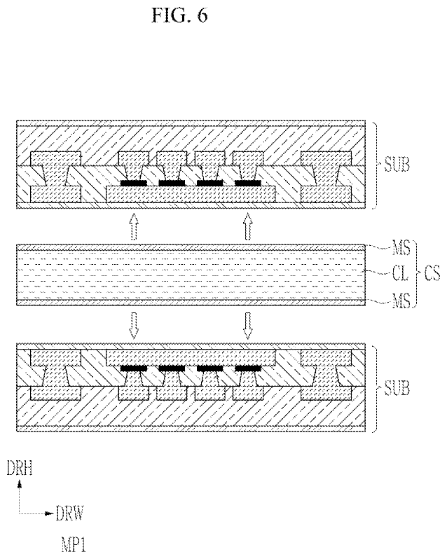

Next, as shown in FIG. 6. a substrate portion SUB is peeled from both sides of the carrier substrate CS.

Hereinafter, one substrate portion SUB peeled from the carrier substrate CS will be described.

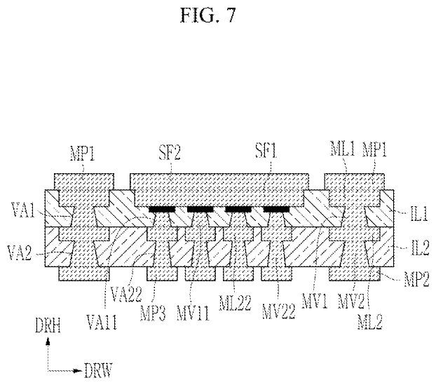

As shown in FIG. 7, the first copper foil layer TC1 is removed from the substrate portion SUB, a second sacrificial layer SF2 is formed on the first sacrificial layer SF1, and the first pad layer MP1 is formed on the first wiring layer ML1. In addition, the third via hole VA2 overlapping the second wiring layer ML2 and the fourth via hole VA22 overlapping the third wiring layer ML22 are formed in the second insulating layer IL2, the third via MV2 is formed within the third via hole VA2 and the fourth via MV22 is formed within the fourth via hole VA22, and the second pad layer MP2 overlapping the third via MV2 and the third wiring layer ML22 overlapping the fourth via MV22 are formed.

In the present embodiment, the third via hole VA2, the fourth via hole VA22, the third via MV2, the fourth via MV22, the second pad layer MP2, and the third wiring layer ML22 are formed after the substrate portion SUB is peeled from the both sides of the carrier substrate CS, but the embodiment is not limited thereto. According to another embodiment, the third via hole VA2, the fourth via hole VA22, the third via MV2, the fourth via MV22, the second pad layer MP2, and the third wiring layer ML22 are formed before the substrate portion SUB is peeled from the both sides of the carrier substrate CS.

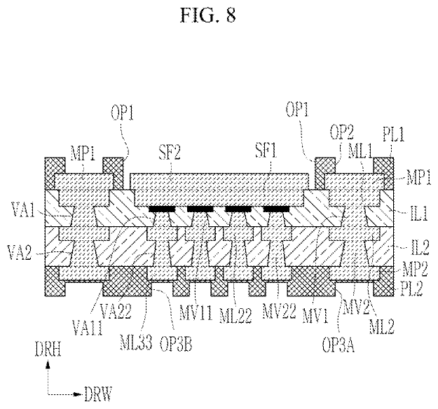

Referring to FIG. 8, the first solder resist layer PL1 is formed on the first insulating layer IL1, and the second solder resist layer PL2 is formed below the second insulating layer IL2.

The first solder resist layer PL1 may include a first opening OP1 that exposes all of the second sacrificial layer SF2 and the second opening OP2 that overlaps at least a portion of the first pad layer MP1, and the second solder resist layer PL2 may include the third opening OP3A overlapping the second pad layer MP2 and the fourth opening OP3B overlapping the third wiring layer ML22.

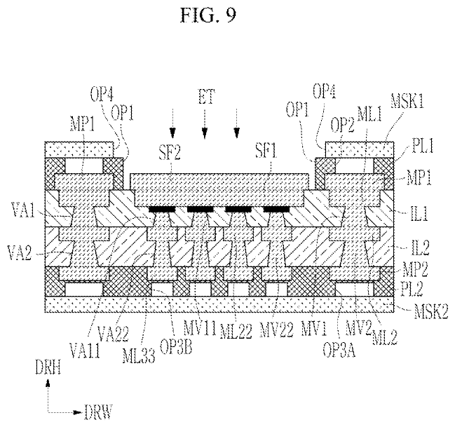

As shown in FIG. 9, a first mask layer MSK1 covering the second opening OP2 of the first solder resist layer PL1 on the first solder resist layer PL1 and exposing the first opening OP1 is disposed, and a second mask layer MSK2 is disposed below the second solder resist layer PL2 to cover the third opening OP3A and the fourth opening OP3B. A portion except a region where the cavity CV will be formed may be covered by the first mask layer MSK1 and the second mask layer MSK2.

The first sacrificial layer SF1 and the second sacrificial layer SF2 disposed at a region where the cavity CV will be formed are etched (ET) using the first mask layer MSK1 and the second mask layer MSK2 as etching masks.

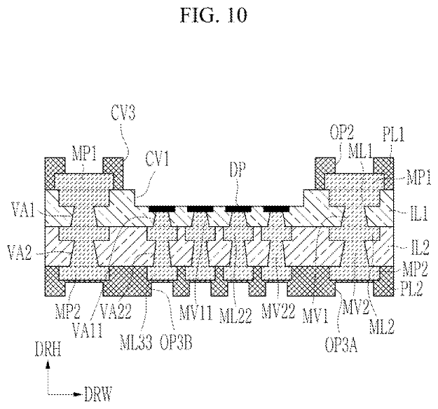

Referring to FIG. 10, the first mask layer MSK1 and the second mask layer MSK2 are removed so that the first portion CV1 of the cavity CV is formed at a portion of the first insulating layer ML1 and the third portion CV3 of the cavity CV is formed in the first solder resist layer PL1.

Thereafter, the plurality of dummy patterns DP buried in the first insulating layer ML1 are removed to form the second portion CV2 of the cavity CV, so that the printed circuit board 100 of FIG. 1 is formed.

The plurality of dummy patterns DP buried in the first insulating layer ML1 may be removed so that the second via MV11 is exposed through the second portion CV2 of the cavity CV within the cavity CV. Along the height direction DRH, a lower surface of the second portion CV2 of the cavity CV and an upper surface of the second via MV11 may have substantially the same height.

According to the manufacturing method of the printed circuit board according to the present embodiment, the plurality of dummy patterns DP and the first sacrificial layer SF1 may be formed to be buried in the first insulating layer IL1, the second sacrificial layer SF2 may be formed of the same layer as the first pad layer MP1, and the cavity CV may be formed in the printed circuit board by etching the second sacrificial layer SF2, the first sacrificial layer SF1, and the plurality of dummy patterns DP using the mask layers MSK1 and MSK2 as the etching masks. Therefore, the cavity CV may be formed in the first solder resist layer PL1 and a portion of the first insulating layer IL1, and the depth HT of the cavity CV may be greater than a sum of the first thickness D1 of the first wiring layer ML1 buried by the first insulating layer IL1 and the third thickness D3 of the first solder resist layer PL1 by the second depth H2 of the second portion CV2 of the cavity CV.

While the third portion CV3 and the first portion CV1 of the cavity CV are formed, the plurality of vias MV11 may be covered and protected with the plurality of dummy patterns DP. Thus, the plurality of vias MV11 exposed by the cavity CV during a formation process of the cavity CV may be prevented from being damaged so that mounting accuracy is improved when the electronic component is mounted within the cavity CV.

The plurality of wiring layers ML buried within the plurality of insulating layers IL by leaving the first insulating layer IL1 within the cavity CV may be protected by the first insulating layer IL1 so that the circuit pattern around the cavity CV is not damaged, and a thickness of the first wiring layer ML1 buried by the first insulating layer IL1 may be adjusted so that the total depth HT of the cavity CV is adjusted. A surface of the first insulating layer IL1 disposed on a side surface of the second portion CV2 of the cavity CV may protrude from the second portion CV2 to form the plurality of protrusions (PR) on a surface of a lower surface of the cavity CV. The plurality of protrusions (PR) may serve as the spacer, so that if the electronic component is mounted within the cavity CV, the space is generated around the electronic component and heat generated by the electronic component or the like is diffused through the space.

In addition, the plurality of second portions CV2 of the cavity CV may overlap the plurality of second vias MV11, and a connection portion for connection between the electronic component to be mounted within the cavity CV and the printed circuit board 100 may be disposed within a plurality of third portions CV3. Thus, even if a size of the connection portion becomes small, the connection portion may be disposed within the plurality of third portions CV3 so that connection between the electronic component and the printed circuit board 100 is safely maintained.

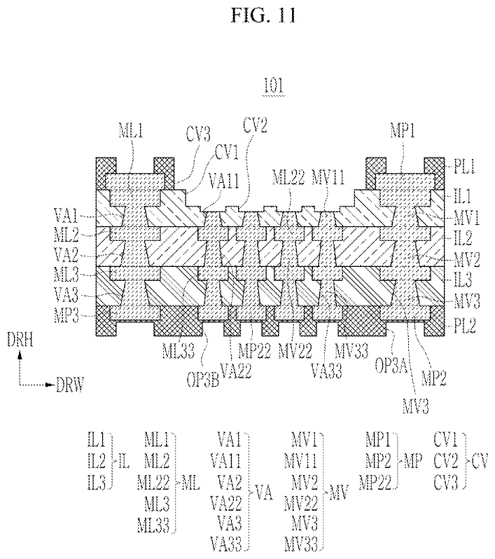

Then, referring to FIG. 11, a printed circuit board according to another embodiment is described. FIG. 11 is a cross-sectional view of the printed circuit board according to the other embodiment.

Referring to FIG. 11, the printed circuit board 101 according to the present embodiment is similar to the printed circuit board 100 according to the embodiment described with reference to FIG. 1. A detailed description of the same component is omitted.

Referring to FIG. 11, unlike the printed circuit board according to the embodiment shown in FIG. 1, the printed circuit board according to the present embodiment may further include a third insulating layer IL3 disposed below the second insulating layer IL2, a fourth wiring layer ML3 and a fifth wiring layer ML33 buried by the third insulating layer IL3, and a fifth via MV3 and a sixth via MV33 disposed in a fifth via hole VA3 and a sixth via hole VA33 of the third insulating layer IL3. The second pad layer MP2 may be connected to the fifth via MV3, and the third pad layer MP22 may be connected to the sixth via MV33.

Many features of the printed circuit board 100 and the manufacturing method of the printed circuit board according to the embodiments previously described with reference to FIGS. 1 to 10 are all applicable to the printed circuit board 101 according to the present embodiment.

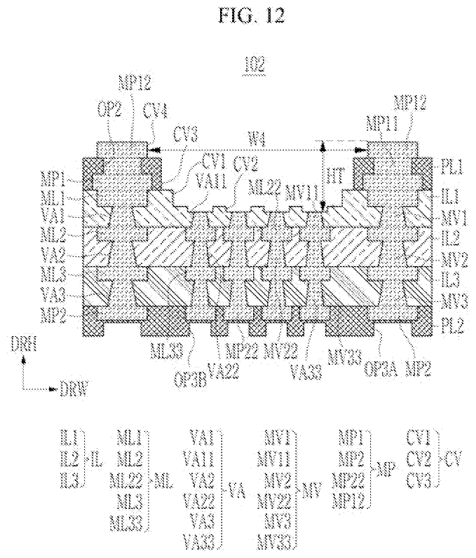

Referring to FIG. 12, a printed circuit board according to another embodiment is described. FIG. 12 is a cross-sectional view of the printed circuit board according to the other embodiment.

Referring to FIG. 12, the printed circuit board 102 according to the present embodiment is similar to the printed circuit boards 100 and 101 according to the embodiments described above. A detailed description of the same component is omitted.

Referring to FIG. 12, unlike the printed circuit board according to the embodiment shown in FIG. 1, the printed circuit board 102 according to the present embodiment may further include the third insulating layer IL3 disposed below the second insulating layer IL2, the fourth wiring layer ML3 and the fifth wiring layer ML33 buried by the third insulating layer IL3, and the fifth via MV3 and the sixth via MV33 disposed in the fifth via hole VA3 and the sixth via hole VA33 of the third insulating layer IL3. The second pad layer MP2 may be connected to the fifth via MV3, and the third pad layer MP22 may be connected to the sixth via MV33.

In addition, unlike the printed circuit boards 100 and 101 according to the embodiments described above, the printed circuit board 102 according to the present embodiment may further include a first additional pad layer MP11 disposed within the second opening OP2 of the first solder resist layer PL1 overlapping at least a portion of the first pad layer MP1 and contacting the first pad layer MP1, and a second additional pad layer MP12 disposed on the first solder resist layer PL1 and contacting the first additional pad layer MP11.

Additionally, the cavity CV may further include a fourth portion CV4 defined as the second additional pad layer MP12.

A fourth width W4 of the fourth portion CV4 of the cavity CV may be different from the first width W1 of the first portion CV1 of the cavity CV formed at the first insulating layer IL1 and the third width W3 of the third portion CV3 of the cavity CV formed at a portion of the first solder resist layer PL1.

A total depth HT of the cavity CV may be substantially equal to a sum of the first thickness D1 of the first wiring layer ML1 buried by the first insulating layer IL1, the thickness of the portion of the first via MV1 within the first via hole VA1 formed in the first insulating layer IL1, the third thickness D3 of the first solder resist layer PL1, and a thickness of the second additional pad layer MP12.

The first additional pad layer MP11 in contact with the first pad layer MP1 and the second additional pad layer MP12 in contact with the first additional pad layer MP11 may be further included so that the total depth HT of the cavity CV is adjusted to be deeper.

Many features of the printed circuit board 100 and the manufacturing method of the printed circuit board according to the embodiments previously described with reference to FIGS. 1 to 10 are all applicable to the printed circuit board 102 according to the present embodiment.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A printed circuit board, comprising:
a first insulating layer;
a first wiring layer that is buried in the first insulating layer;
a first via that is disposed within a first via hole in the first insulating layer;
a second insulating layer that is disposed below the first insulating layer;
a second wiring layer that is buried in the second insulating layer;
a first solder resist layer that is disposed on the first insulating layer; and
a cavity that extends along a height direction by penetrating the first solder resist layer and penetrating a portion of the first insulating layer,
wherein the cavity includes a first portion, a second portion, and a third portion having different widths,
along the height direction, the first portion is disposed on the second portion and the third portion is disposed on the first portion, and
the first via is exposed through the second portion of the cavity.

2. The printed circuit board of claim 1, wherein the second portion of the cavity is plural in number, and a surface of the first insulating layer between the plurality of second portions included in the cavity has a plurality of protrusions protruding toward the first portion.

3. The printed circuit board of claim 2, wherein each of the first via hole and the first via is plural in number, and the plurality of the second portions overlap the plurality of the first vias along the height direction.

4. The printed circuit board of claim 1, wherein a first width of the first portion, a second width of the second portion, and a third width of the third portion are different from each other.

5. The printed circuit board of claim 4, wherein the second width of the second portion is less than each of the first width of the first portion and the third width of the third portion.

6. The printed circuit board of claim 1, wherein a first depth of the first portion is substantially equal to a first thickness of the first wiring layer, and a second depth of the second portion is less than a second thickness of the first via.

7. The printed circuit board of claim 6, wherein a third depth of the third portion is substantially equal to a third thickness of the first solder resist layer.

8. The printed circuit board of claim 1, further comprising:
a second via disposed within a second via hole in the second insulating layer;
a third insulating layer disposed below the second insulating layer; and
a third via disposed within a third via hole in the third insulating layer.

9. The printed circuit board of claim 8, further comprising:
a first pad layer buried by the first solder resist layer;
a first additional pad layer disposed within a cutout portion of the first solder resist layer and contacting the first pad layer; and
a second additional pad layer disposed on the first additional pad layer.

10. The printed circuit board of claim 9, wherein the cavity further includes a fourth portion defined by a side surface of the second additional pad layer.

11. The printed circuit board of claim 10, wherein a width of the fourth portion is different from a first width of the first portion, a second width of the second portion, and a third width of the third portion.

12. A manufacturing method of the printed circuit board, comprising:
forming a first wiring layer and a first sacrificial layer;
forming a plurality of dummy patterns on the first sacrificial layer;
forming a first insulating layer burying the first wiring layer, the first sacrificial layer, and the plurality of dummy patterns;
forming a first via hole overlapping the first wiring layer and a plurality of second via holes overlapping the plurality of dummy patterns in the first insulating layer;
forming a first via and a plurality of second vias in the first via hole and the plurality of second via holes of the first insulating layer;
forming a second sacrificial layer on the first sacrificial layer;
forming a first portion of a cavity by etching the second sacrificial layer and the first sacrificial layer; and
removing the plurality of dummy patterns to form a second portion of the cavity so that the plurality of second vias are exposed.

13. The manufacturing method of claim 12, wherein the first sacrificial layer includes the same layer as the first wiring layer and is formed to have substantially the same thickness as that of the first wiring layer, and the plurality of dummy patterns include a layer different from the first via and are formed to have a thickness less than a thickness of the first via.

14. The manufacturing method of claim 13, further comprising:
forming a pad layer that is the same layer as the second sacrificial layer on the first wiring layer; and
forming a first solder resist layer that covers the pad layer, exposes the second sacrificial layer, and has a third portion of the cavity.

15. The manufacturing method of claim 14, further comprising:
forming a third insulating layer disposed below a second insulating layer disposed below the first insulating layer; and
forming a third via disposed within a third via hole formed in the third insulating layer.

16. The manufacturing method of claim 15, further comprising:
forming a first additional pad layer disposed within a cutout portion of the first solder resist layer and contacting a first pad layer buried by the first solder resist layer; and
forming a second additional pad layer disposed on the first additional pad layer.

17. The manufacturing method of claim 16, wherein the cavity is formed to further include a fourth portion defined by a side surface of the second additional pad layer.

18. The manufacturing method of claim 17, wherein a second width of the second portion is less than each of a first width of the first portion and a third width of the third portion, and
a width of the fourth portion is formed differently from the first width of the first portion, the second width of the second portion, and the third width of the third portion.

19. The manufacturing method of claim 14, wherein a first width of the first portion, a second width of the second portion, and a third width of the third portion are different from each other.

20. The manufacturing method of claim 19, wherein the second width of the second portion is less than each of the first width of the first portion and the third width of the third portion.
